(19) United States
(12) Patent Application Publication
(10) Pub. No.: US 2007/0126055 A1
(43) Pub. Date: Jun. 7, 2007

(54) Trench insulated gate field effect transistor

(75) Inventors: Raymond J. E. Hueting, Hergelo (NL); Erwin A. Hijzen, Blanden (BE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., EINDHOVEN (NL)

(21) Appl. No.: 10/580,625

(22) PCT Filed: Nov. 26, 2004
(86) PCT No.: PCT/IB04/52562

§ 371 Date: May 24, 2006

(30) Foreign Application Priority Data
Nov. 29, 2003 (GB) 0327792.8

(51) Int. Cl. H01L 29/94

(52) U.S. Cl. 257/330

(57) ABSTRACT

The invention relates to a trench MOSFET with drain (8), drift (10) body (12) and source (14) regions. The drift region is doped to have a high concentration gradient. A field plate electrode (34) is provided adjacent to the drift region (10) and a gate electrode (32) next to the body region (12).

The invention relates to a trench insulated gate field effect transistor (IGFET), and particularly but not exclusively to a trench MOSFET (metal oxide semiconductor field effect transistor) structure suitable for use as Control and Sync FETs at low or medium breakdown voltages.

Low-voltage trench MOSFETs are commonly used, for example in voltage regulator modules (VRMs) in power supplies for electronic equipment such as personal computers.

Commonly, a pair of MOSFETs are used, known as a Control FET and a Sync FET. The ideal characteristics of these FETs differ slightly. For the Sync FET the conduction power loss should be as low as possible. Since the conduction power loss is proportional to the specific on-resistance (R_{ds,on}) this parameter should be reduced. For the Control FET on the other hand the switching loss should be minimised, the switching loss being proportional to the gate-drain charge density (Q_{gd}).

A figure of merit (FOM) has been defined as the multiple of R_{ds,on} and Q_{gd} to provide an indication of how suitable a transistor is in for use in VRMs. Note that the smaller the FOM the better. There is a need for structures that provide an improved figure of merit.

There is a drive to reduce the dimensions of trench MOSFETs, as for transistors generally. In the context of the devices considered here, the main benefit of this is to reduce the active area and so reduce R_{ds,on}. Such reduced size trench MOSFETs can be made, for example, using deep ultra-violet lithography.

However, this reduction in size is not necessarily attractive for the Control FET since in a conventional structure the gate drain charge density Q_{gd} increases drastically with reduced size. Thus, simply reducing the size of the structure does not give improvements as large as might be expected.

There is thus a need for an improved structure to give improved properties of FETs for VRMs.

US-A-2003/0047768 describes a high voltage transistor with a low specific on-state resistance which is said to support a high voltage in the off state. In an embodiment, a drift region is used having a graded doping starting at 5×10¹⁵ cm⁻³ near the p-body region and ending at around 1×10¹⁷ cm⁻³ near the substrate.

Another power transistor is described in EP-A-1168455, with properties intended to improve the on-resistance. In this case, a field plate is provided adjacent a drift region, separated by a thick insulator from the drift region. A separate gate is provided separated by a thin gate insulator from the body region.

Other structures with graded drift regions are known. For example, U.S. Pat. No. 5,998,833 describes a structure having a drift region concentration varying by a factor of twenty adjacent to a trench having separate gate and source regions.

According to the invention there is provided an insulated gate field effect transistor, comprising:

a semiconductor body having opposed first and second major surfaces;

a source region of first conductivity type at the first major surface;

a body region of second conductivity type opposite to the first conductivity type under the source region;

a drift region of first conductivity type under the body region;

a drain region of first conductivity type under the drift region, so that the source, body, drift and drain regions regions extend in that order from the first major surface towards the second major surface; and

insulated trenches extending from the first major surface towards the second major surface past the source region and the body region into the drift region, each trench having sidewalls, and including insulator on the sidewalls, at least one conductive gate electrode adjacent to the body region separated from the body region by a gate insulator, and at least one conductive field plate electrode adjacent to the drift region separated from the drift region by a field plate insulator, and a gate-field plate insulator separating the field plate from the gate,

wherein the source regions and trenches define a pattern of cells across the first major surface;

the doping concentration in the drift region increases from the part of the drift region adjacent to the body region to the part of the drift region adjacent to the drain region, the doping concentration in the drift region being at least 50 times greater adjacent to the drain region than adjacent to the body region.

By providing a steeply graded concentration gradient in the drift region it is possible to achieve structures having both a low specific on-resistance and a low switching loss.

Calculations suggest that increased concentration gradients in the drift regions produce improved results at low breakdown voltages. Accordingly, in preferred embodiments, the doping concentration in the drift region is such that the doping concentration adjacent to the drift region is higher than the doping concentration adjacent to the body region by a factor of at least 100, further preferably at least 200.

Structures with field plates are known in particular for use with high breakdown voltages of at least 50V and generally higher. The inventors have realised that field plate structures are also applicable to low voltage power MOSFETs with breakdown voltages of 30V and below, even though the channel resistance forms the major contribution to resistance in such devices.

One reason for the usefulness of the structure proposed in lower voltage devices is that the depth of the body region can be reduced below prior values. In particular, the distance between source region and drift region adjacent to the gate may be no more than 0.4 micron. It might be thought that such low body thicknesses would result in problems of punch-through, but the field plate and the consequential reduced surface field effect raise the source-drain voltage at which punch-through occurs.

Preferably, the gate-field plate insulator has a thickness greater than or equal to the field plate oxide thickness. The thicker dielectric between the gate and the field plate avoids excessive capacitative coupling to the gate.

In preferred embodiments, the first conductivity type is n-type and the second conductivity type p-type.

The transistor preferably includes a three-dimensional pattern of cells defined by the source regions and trenches arranged across the first major surface. By “three-dimensional” is meant a pattern where the cells repeat not just in one direction across the substrate, as in a striped pattern, but both laterally and longitudinally, as well as extending vertically into the substrate. In a preferred embodiment, a hexagonal pattern is used.

Note that the cell patterns may be defined using separate islands of source region, surrounded by a continuous linked pattern of trenches.

In particular embodiments, the cell pitch is less than 2 microns, preferably less than 1 micron.

The inventors have identified a difficulty with such three-dimensional patterns in the context of structures according to the present invention, especially when the patterns are small (i.e. have a low cell pitch) in that they can have a low threshold voltage.

Conventionally, n-type doped polysilicon may be used for the gate electrode. However, in preferred arrangements of the invention p-type doped silicon, preferably polysilicon, may be used instead. This addresses the difficulty of a low threshold voltage which can occur in narrow devices. The use of p-type silicon as the gate electrode can increase the threshold voltage to suitable levels.

The use of p-type polysilicon as the gate electrode has particular benefits in the case that a two-dimensional pattern of cells (for example a hexagonal pattern) is used instead of stripes.

Preferably, the gate-field plate insulator is thicker than the gate insulator. The gate insulator may be formed either by local oxidation of silicon (LOCOS) or by a uniform deposition of insulator.

In embodiments, a Schottky contact is provided to the source. This is particularly suitable for arrangements using a three-dimensional pattern cell geometry. Alternatively, by using a moat etch filled with a metal or conductive material extending through the source region to the body region the source contact may be connected to the source region and the body region.

The inventors have identified that a particular advantage of the use of three-dimensional cell patterns is that they permit significantly increased doping concentration gradients. Thus, the inventors have realised that useful structures can be created using the combination of p-type polysilicon gates, low cell pitch pattern structures with very high doping concentration gradients in the drift region.

The field plate electrode may in some embodiments be connected to the source.

In other embodiments the field plate electrode may be connected to a; separate terminal for independent control. By applying an appropriate voltage to the field plate electrode an inversion layer can be created in the sub-channel region thereby lowering the on-resistance of the device. In particular, a negative applied voltage may be applied. By using such a negative voltage an increased thickness of the insulation between the field plate electrode and the drift region may be used, thereby reducing capacitative coupling.

Note that in this specification the term “over” is used for the direction towards the first major surface and “under” for the direction towards the second major surface without any orientation in space of the transistor being intended.

Embodiments of the invention will now be described, purely by way of example, with reference to the accompanying drawings in which:

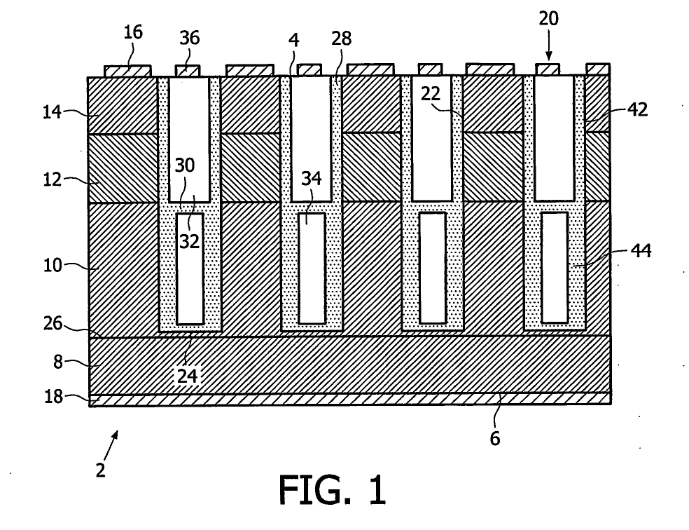

FIG. 1 shows a cross-sectional side view of a MOSFET according to a first embodiment of the invention;

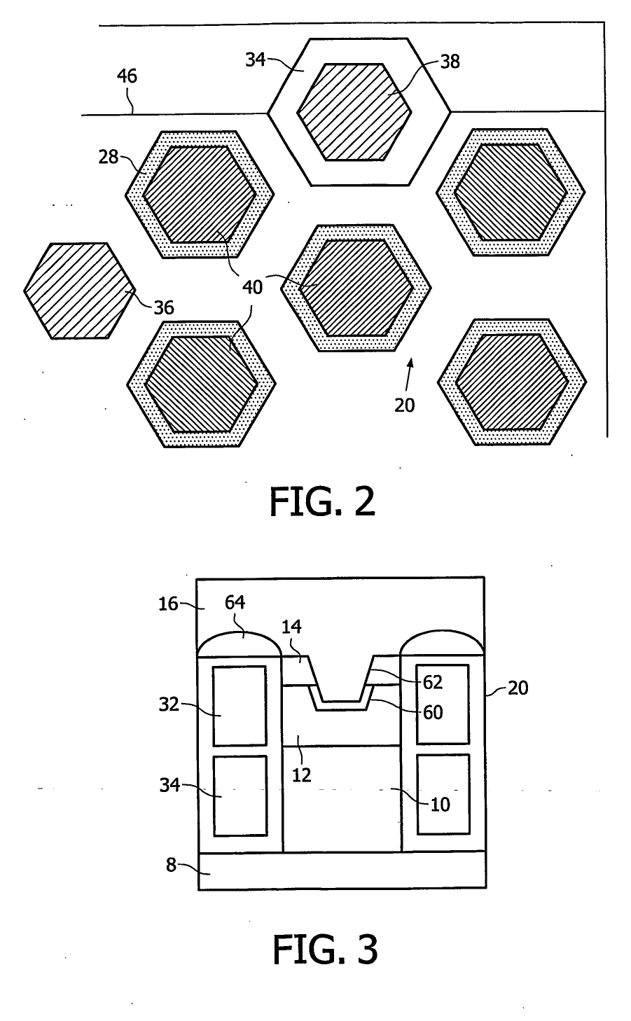

FIG. 2 shows a top view of the embodiment of FIG. 1;

FIG. 3 is a detail cross-section showing a moat etch used for contacting to the source and body layers;

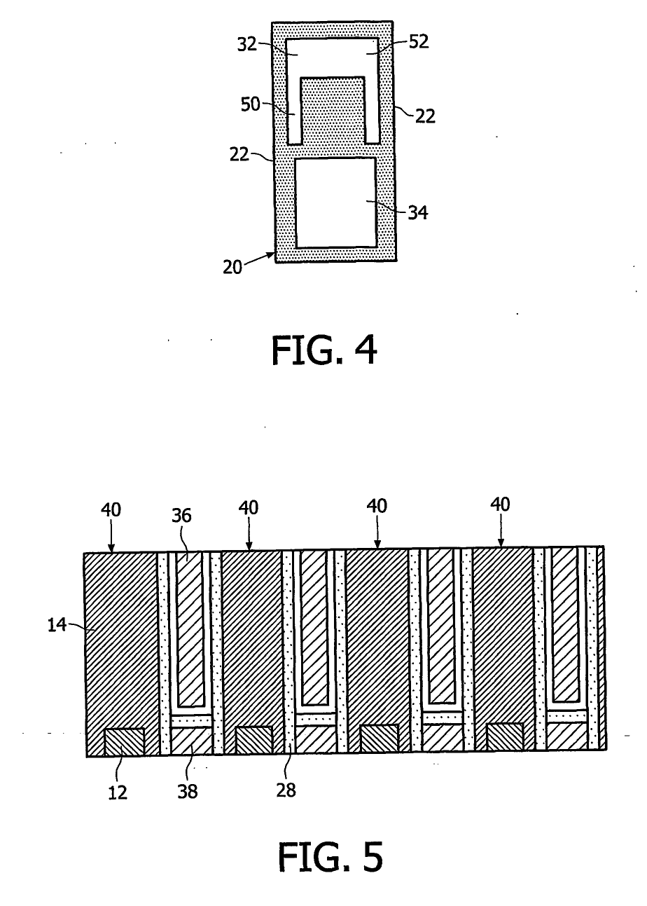

FIG. 4 shows a side cross-sectional view of a modification of the gate shape according to the invention; and

FIG. 5 shows a top view of a second embodiment of a MOSFET according to the invention.

Note that the drawings are schematic and not to scale. Like reference numerals are used for the same or similar features in different figures.

FIG. 1 shows a cross-section through a semiconductor device according to a first embodiment of the invention. A semiconductor body 2 has opposed first 4 and second 6 major surfaces. An n+drain region 8 adjoins the second major surface. A graded concentration n-type drift region 10 is provided on top of the drain region 8, a p body region 12 on top of the drift region 10 and an n+ source region 14 on top of the body region 12. A source contact 16 is provided on the first major surface 4 to connect to the source region 14 and a drain contact 18 is provided on the second major surface 6 to connect to the drain region.

A trench 20 extends from the first major surface 4 through the source region 14, the body region 12 and the drift region 10, having sidewalls 22 and a base 24 close to the drain region-drift region interface 26. The trench extends substantially the full depth of the drift region 10.

As illustrated in FIG. 2, in the specific example, a plurality of cells 40 extend in a hexagonal array across the first major surface. The cells are provided in a mesa region delimited by mesa boundary 46. Each cell includes a stack of a source region 14 over the body region 12 and drift region 10 as shown in FIG. 1. The cells are separated by the insulated trenches 20.

Gate oxide 28 is provided on the sidewalls 22. Gate oxide 28 is also provided on the base 24 of the trench 20, above which there is a conductive field plate 34. This is covered by insulator 30, above which in the same trench 20 is provided an n-type polysilicon gate 32 adjacent to the source region 14 and body region 12. The insulator 30 may be formed by local oxidation of silicon (LOCOS) or by deposition—the oxide is thicker than the gate oxide 28 to reduce capacitative coupling between the field plate 34 and the gate 32.

A gate contact 36 connects to the gate 32 and a field plate contact 38 (FIG. 2) contacts the field plate 34. Note that the field plate contact 38 is in this embodiment arranged at the edge of the substrate away from the central mesa 46 having the semiconductor cells 40 and the gate 32. The field plate contact connects to an extension of the field plate 34 outside the central mesa.

FIG. 3 shows how the source contact 16 is connected to both source region 14 and body 12 using a moat etch, i.e. a trench 62 filled with metal in the centre of the cell in combination with a p+ contact implantation 60 in the body region 12 to make a good contact to the body region 12. The contact implantation 60 is optional and may be omitted if not required.

The source contact 16 may extend over the substrate, separated by an insulator 64 over the trenches 20 and connecting to the source region 14.

Further, in embodiments where the field plate 34 is connected to the source potential, a single metallisation may function as the source contact 16 and field plate contact 38.

In the specific example shown, the source region 14 extends to a depth of 0.25 micron from the first major surface with a doping concentration of 10²⁰ to 10²¹ cm⁻³. The body region 12 extends below the source profile for a further 0.35 micron to a total depth of 0.6 micron. The body region 14 is doped p-type at a doping density of 1×10¹⁷ cm⁻¹.

The drift region 10 extends for a further 1 micron to a depth of 1.6 microns below the first major surface 4. The doping is n-type and linearly graded starting from a density of 1×10¹⁶ cm⁻³ at the upper end of the drift region 10 and rising to a doping density of 2×10¹⁸ cm⁻³ at the lower end adjacent to the drift region 8. The oxide 28 thickness is 0.39 micron adjacent to the gate 32 and 0.8 micron adjacent to the field plate 34.

In the example, the cell pitch is 0.5 micron, and the trench is 1.6 microns deep and 0.25 micron wide.

These specific values are for a 25V control FET.

Calculations were carried out assuming an ohmic source contact 16 contacting both source 14 and body 12 and also connected to the field plate 34. This may be achieved using the moat etch as described above such that a proper ohmic contact is formed between source and body.

The results show a threshold voltage of 1.2V, an R_{ds,on} value of 0.65 mΩ·mm² excluding the substrate resistance and an excellent Q_{gd} value of 0.63 nC/mm² for an applied voltage of 12V. This gives a figure of merit of 0.4 mΩ·nC. A benefit of the invention is that it allows improvements both in the R_{ds,on} value and the Q_{gd} value. The inventors believe that this may well be due to the combination of the large gradient of doping density in the drift region 8 as well as the hexagonal geometry.

Breakdown occurred at a voltage of 25V—the breakdown point was located near the trench sidewall at a depth of 1.1 microns.

The figure of merit of a recently published LDMOS structure (Ludikhuize A W, ISPSD p 301-304, 2002) is 22 mΩ·nC. This is for a larger cell size but even scaling to a 0.5 μm pitch still gives rise to a Q_{gd} of 6.6 nC/mm². Thus the invention provides much better results than this published value.

The threshold voltage is rather low. Accordingly, a preferred modification of the first embodiment is to use a p-type polysilicon gate 32 to increase the threshold voltage.

To avoid practical problems in connecting an ohmic source contact to, the source region 14, a Schottky source contact may be connected to the source region 14 instead.

A further possible modification is to reduce the depth of the p-type body region 12 and increase the doping density.

In a yet further modification of the first embodiment the field plate terminal 38 is not connected to the source contact 16 but is instead biased negatively. This allows a thicker oxide to be used for the dielectric between field plate 34 and drift region 10, or alternatively a dielectric with a lower dielectric constant.

FIG. 4 shows the trench of an alternative embodiment in section in which the gate 32 is shaped to have an inverted cup-shape so that it has a reduced capacitative coupling to the field plate 34 when the field plate 34 is connected to the source. The side pieces 50 of the cup are polysilicon spacers adjacent to the side walls 22 of the trench 20 and the top piece 52 is substantially flat.

In an alternative embodiment, shown in top view in FIG. 5, a stripe pattern is used instead of a hexagonal arrangement of cells. FIG. 5 shows an ohmic field plate contact 38 to the field plate at one end of each of the stripes, as well as the exposure of the body region 12 at the first major surface 4. The body region 12 is connected to the source contact 16 in this exposed region.

The cell pitch remains 0.5 micron, but the trench is only 1.4 microns deep, to correspond to the drift region 10 which extends from a depth of 0.6 micron for 0.8 micron i.e. to a total depth of 1.4 microns.

The drift region 12 doping is n-type and linearly graded starting from a density of 1×10¹⁶ cm⁻³ at the upper end of the drift region 10 and rising to a doping density of 1×10¹⁸ cm⁻³ at the lower end adjacent to the drift region 8. Thus, the gradient of doping density is not as steep as that used in the first embodiment above, in view of the reduced RESURF effect in the first embodiment. These values are chosen to give the same breakdown voltage of 25V, as confirmed by calculation: the device is as before a 25V control FET.

The simulated results give a threshold voltage of 2.1 V, an R_{ds,on} value of 0.75 mΩ·mm² excluding the substrate resistance and a Q_{gd} value of 2.2 C/mm² for an applied voltage of 12V. This gives a figure of merit of 1.65 mΩ·nC.

Thus, in this embodiment significantly improved values are obtained compared with the prior art, though the figure of merit is not as good as that obtained in the first embodiment. The increased resistance is believed to result from the reduced doping density gradient and the worse gate drain capacitance value to the different geometry.

Thus the results show that for the same breakdown voltage significantly improved figures of merit are obtained using a three-dimensional pattern of cells as in the first embodiment as compared with those obtained in a stripe structure as in the second embodiment.

In a modification of the embodiment of FIG. 5 for 20V breakdown instead of 25V, the trench depth is 1.3 microns and the body and source depths remained unchanged. The drift region doping density increases from 10¹⁶ cm⁻³ adjacent to the body region to 10¹⁸ cm⁻³ adjacent to the drain region. In this structure, the field plate oxide 44 thickness is the same as the gate oxide thickness.

From reading the present disclosure, other variations and modifications will be apparent to persons skilled in the art. Such variations and modifications may involve equivalent and other features which are already known in the design, manufacture and use of semiconductor devices and which may be used in addition to or instead of features described herein. Although claims have been formulated in this application to particular combinations of features, it should be understood that the scope of disclosure also includes any novel feature or any novel combination of features disclosed herein either explicitly or implicitly or any generalisation thereof, whether or not it mitigates any or all of the same technical problems as does the present invention. The applicants hereby give notice that new claims may be formulated to any such features and/or combinations of such features during the prosecution of the present application or of any further applications derived therefrom.

For example, the oxide dielectric in the trench can be replaced with nitride or oxynitride. This should increase Q_{gd} but decrease R_{ds,on}. A low-k material may be used which should have the opposite effect.

Further, instead of a hexagonal cell pattern a square, triangular or other cell pattern may be used instead.

The embodiments are of n-type MOSFETs but p-type MOSFETs are also possible. Further, there is no need to use silicon, but the invention is also applicable to other group IV, III-V or II-VI semiconductors and indeed any other semiconductor material.

1. An insulated gate field effect transistor, comprising:
a semiconductor body having opposed first and second major surfaces;
a source region of first conductivity type at the first major surface;
a body region of second conductivity type opposite to the first conductivity type under the source region;
a drift region of first conductivity type under the body region;
a drain region of first conductivity type under the drift region, so that the source, body, drift and drain regions regions extend in that order from the first major surface towards the second major surface; and
insulated trenches extending from the first major surface towards the second major surface past the source region and the body region into the drift region, each trench having sidewalls, and including insulator on the sidewalls, at least one conductive gate electrode adjacent to the body region separated from the body region by a gate insulator, and at least one conductive field plate electrode adjacent to the drift region separated from the drift region by a field plate insulator, and a gate-field plate insulator separating the field plate from the gate,
wherein the source regions and trenches define a pattern of cells across the first major surface; and
the doping concentration in the drift region increases from the part of the drift region adjacent to the body region to the part of the drift region adjacent to the drain region the doping concentration in the drift region being at least 50 times greater adjacent to the drain region than adjacent to the body region.

2. An insulated gate field effect transistor according to claim 1 in which the gate electrode is of conductive semiconductor doped to be the second conductivity type.

3. An insulated gate field effect transistor according to claim 1 wherein the gate electrode has side pieces spaced apart adjacent to the sidewalls on either side of the trench and a top piece spanning the gap between the side pieces.

4. An insulated gate field effect transistor according to claim 1 wherein the breakdown voltage is less than or equal to 30V.

5. An insulated gate field effect transistor according to claim 1 wherein the pattern of cells defined by the source regions and trenches arranged across the first major surface is a pattern in which cells repeat in more than one direction across the surface to form a three-dimensional cell structure.

6. An insulated gate field effect transistor according to claim 5 wherein the cells are arranged in a hexagonal pattern.

7. An insulated gate field effect transistor according to claim 1 further comprising a trench filled with conductive material extending through the source region to the body region to connect the source contact to the source region and the body region.

8. An insulated gate field effect transistor according to claim 7 further comprising
a doped contact region of second conductivity type in the body region in contact with the conductive material in the trench, the doping concentration in the doped contact region being higher than the doping in the rest of the body region.

9. An insulated gate field effect transistor according to claim 1 wherein the thickness of the insulator thickness adjacent to the field plate electrode is greater than the thickness of the insulator adjacent to the gate electrode.

10. An insulated gate field effect transistor according to claim 1 wherein the cell pitch is not greater than 1 micron.

11. An insulated gate field effect transistor according to claim 1 wherein the first conductivity type is n-type, the second conductivity type is p-type and the gate is of p-type doped polysilicon.

12. An insulated gate field effect transistor according to claim 1 wherein the field plate oxide thickness is in the range 0.6 to 1 micron and the gate oxide thickness is in the range 0.2 to 0.5 micron.

13. An insulated gate field effect transistor according to claim 1 wherein the field plate electrode is connected to the source.

14. An insulated gate field effect transistor according to claim 1 further comprising
a field plate terminal connected to the field plate for controlling the field plate voltage independently.
